(19) United States
(12) Patent Application Publication
(10) Pub. No.: US 2007/0241370 A1
(43) Pub. Date: Oct. 18, 2007

(54) Semiconductor memory device

(76) Inventor: Yutaka Terada, Osaka (JP)

Correspondence Address: MCDERMOTT WILL & EMERY LLP, 600 13TH STREET, NW, WASHINGTON, DC, 20005-3096, US

(21) Appl. No.: 11/783,462

(22) Filed: Apr. 10, 2007

(30) Foreign Application Priority Data
Apr. 18, 2006 (JP) 2006-114204

(51) Int. Cl. H01L 27/10

(52) U.S. Cl. 257/208

(57) ABSTRACT

A gate electrode of a MOS transistor connected with a word line and a bit line in an SRAM has a projection extending in a direction away from a contact electrically connecting a drain region of the MOS transistor and the bit line. A contact electrically connecting the gate electrode and the word line is provided in the projection of the gate electrode.

### CROSS-REFERENCE TO RELATED APPLICATION

This application claims priority under 35 U.S.C. §119 to Japanese Patent Application No. 2006-114204 filed on Apr. 18, 2006, the entire contents of all of which are incorporated herein by reference.

### BACKGROUND OF THE INVENTION

The present invention relates to semiconductor memory devices, and particularly relates to a semiconductor memory device including an SRAM.

SRAM memory cells are composed of CMOS transistors alone, and thus can be fabricated in the same process as logic circuits. In particular, an SRAM memory cell consisting of six transistors is excellent in terms of operation range and power consumption and is widely used.

Also, it is possible to integrate an SRAM capable of high-speed operation and a DRAM capable of having a high capacity on a single chip by using a common interconnect layer for the SRAM and the DRAM. This enables system LSIs, etc. to increase in performance.

In an SRAM, a memory cell is electrically connected with a bit line by activating a word line, and data is read by variation in the potential of the bit line. The speed of the bit-line potential variation depends on the current flowing through the bit line and the capacitance of the bit line. If the current is constant, the bit-line potential variation becomes slower by increasing the capacitance of the bit line.

The capacitance of a bit line depends on the parasitic capacitance of an interconnect layer and the parasitic capacitance of a contact connected with the interconnect layer. Thus, the larger the parasitic capacitance of the contact, the lower the data read speed. The parasitic capacitance of a contact is increased, as the distance between a contact connected with a bit line and a contact connected with a word line is decreased.

In a semiconductor memory device in which a DRAM having stacked capacitors and an SRAM are both included, a bit line is provided in a layer above the stacked capacitors. The distance between the bit line and a transistor's electrode is thus large, and hence the length of the contact connecting the bit line and the transistor's electrode is increased. The parasitic capacitance of the contact connected with the bit line is thus increased further. As a result, in the semiconductor memory device including both the SRAM and the DRAM, the speed at which data is read from the SRAM might slow down significantly.

### SUMMARY OF THE INVENTION

In view of the above problem, it is therefore an object of the present invention to provide a semiconductor memory device including an SRAM, in particular, a semiconductor memory device including both an SRAM and a DRAM having stacked capacitors, in which the parasitic capacitance of a contact connected with a bit line is reduced.

In order to achieve the object, in a first inventive semiconductor memory device including an SRAM, a gate electrode of a MOS transistor connected with a word line and a bit line in the SRAM has a projection extending in a direction away from a contact electrically connecting a drain region of the MOS transistor and the bit line, and a contact electrically connecting the gate electrode and the word line is provided in the projection.

In the first inventive semiconductor memory device, it is possible to increase the distance between the contact connecting the gate electrode and the word line and the contact connecting the drain region and the bit line. Thus, the parasitic capacitance of the contact connected with the bit line is reduced.

Also, in order to achieve the object, a second inventive semiconductor memory device including an SRAM includes: a conductive projection, which is in contact with a gate electrode of a MOS transistor connected with a word line and a bit line in the SRAM and extends in a direction away from a contact electrically connecting a drain region of the MOS transistor and the bit line, and a contact electrically connecting the projection and the word line.

In the second inventive semiconductor memory device, it is possible to increase the distance between the contact connecting the gate electrode and the word line via the projection and the contact connecting the drain region and the bit line. Thus, the parasitic capacitance of the contact connected with the bit line is reduced.

Furthermore, in order to achieve the object, in a third semiconductor memory device including an SRAM, a first MOS transistor and a second MOS transistor are connected to a common word line in the SRAM and have a common gate electrode, and a contact that electrically connects the gate electrode and the word line is provided outside a region surrounded by contacts that are connected with a drain region and a source region respectively of the first MOS transistor and by contacts that are connected with a drain region and a source region respectively of the second MOS transistor.

In the third semiconductor memory device, it is possible to increase the distance between at least one of the contacts connected with a bit line and the contact connecting the gate electrode and the word line. Thus, the parasitic capacitance of the at least one of the contacts connected with the bit line is reduced significantly.

Preferably, a bit line and an inverted bit line in the SRAM are twisted together, the inverted bit line being obtained by inverting logic of the bit line. This enables the capacitances of the bit line and inverted bit line to be equal.

Specifically, the semiconductor memory device including the SRAM includes a DRAM, wherein the bit line in the SRAM and a bit line in the DRAM are formed in a common interconnect layer. More specifically, the DRAM has a stacked capacitor, and the layer where the bit lines are formed is above the capacitor.

As described above, according to the present invention, in a semiconductor memory device including an SRAM, in particular, in a semiconductor memory device including both an SRAM and a DRAM having stacked capacitors, the parasitic capacitance of a contact connected with a bit line is reduced, whereby it is possible to read data from the SRAM at high speed.

### BRIEF DESCRIPTION OF THE DRAWINGS

FIG. 1 illustrates the layout of an SRAM memory cell according to a first embodiment.

FIG. 2 illustrates the layout of an SRAM memory cell according to a second embodiment.

FIG. 3 is a cross-sectional view taken along the line II-II′ of FIG. 2.

FIG. 4 illustrates the layout of an SRAM memory cell according to a third embodiment.

### DETAILED DESCRIPTION OF THE INVENTION

Hereinafter, the preferred embodiments of the present invention will be described with reference to the accompanying drawings.

### First embodiment

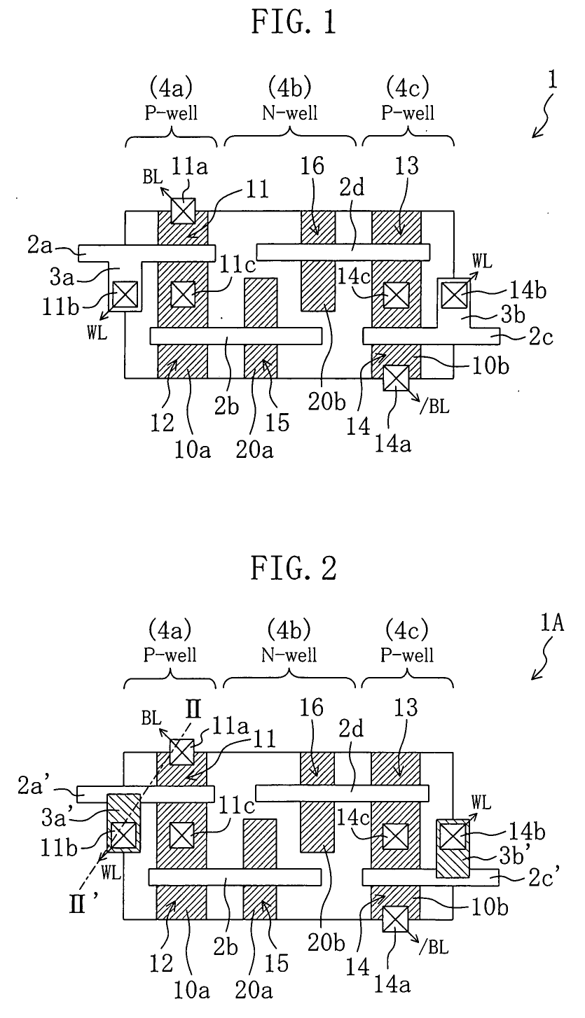

FIG. 1 illustrates the layout of an SRAM memory cell according to a first embodiment. An SRAM memory cell (hereinafter also referred to simply as a “memory cell”) 1 includes nMOS transistors 11 and 12, pMOS transistors 15 and 16, and nMOS transistors 13 and 14. The source and drain regions of the nMOS transistors 11 and 12 are in an n-type doped region 10a formed in a p-well region 4a in the left-hand portion of FIG. 1. The source and drain regions of the pMOS transistors 15 and 16 are in P-type doped regions 20a and 20b, respectively, formed in an n-well region 4b in the middle portion of FIG. 1. The source and drain regions of the nMOS transistors 13 and 14 are in an n-type doped region 10b formed in a p-well region 4c in the right-hand portion of FIG. 1.

The pair of the nMOS and pMOS transistors 12 and 15, having a common gate electrode 2b, and the pair of the nMOS and pMOS transistors 13 and 16, having a common gate electrode 2d, each form an inverter. The output of one of the two inverters is connected with the input of the other so as to form an inverter ring. Information in the memory cell 1 is stored in this inverter ring.

The drain regions of the nMOS transistors 11 and 14 are respectively connected to bit lines BL and /BL by contacts 11a and 14a. The bit line /BL is the logical inverse of the bit line BL. The source regions of the nMOS transistors 11 and 14 are connected with the inverter ring by respective contacts 11c and 14c. The gate electrodes 2a and 2c of the nMOS transistors 11 and 14 are connected to a common word line WL by respective contacts 11b and 14b and are connected together by a higher level interconnect. The memory cell 1 includes other interconnects and contacts that are not shown in FIG. 1, but they are not particularly related to the present invention, and the description thereof will be thus omitted herein.

The gate electrode 2a has a projection 3a extending in the direction away from the contact 11a, that is, the downward direction in FIG. 1. The contact 11b is formed in the projection 3a of the gate electrode 2a. By this structure, the distance between the contacts 11a and 11b is increased, whereby it is possible to reduce the parasitic capacitance of the contact 11a that would be otherwise produced by the adjoining contacts 11a and 11b.

It is desirable that the distance between the contacts 11a and 11b be as long as possible. To be specific, the end of the projection 3a may be extended downwardly in FIG. 1 as much as possible, and the contact 11b may be formed in the end portion of the projection 3a. Then, the parasitic capacitance of the contact 11a is reduced more effectively.

On the other hand, the distance between the contacts 11b and 11c is shortened, causing the respective parasitic capacitances of the contacts 11b and 11c to increase. However, since the word line WL connected to the contact 11b is driven by a word driver (not shown) having high drive capability, the operation speed is hardly affected, even if the parasitic capacitance is increased. Also, the contact 11c is connected with the inverter ring, and therefore the storage capacitance of the inverter ring is also increased by the parasitic capacitance increase. This is favorable in terms of data stability. For example, the reduced distance between the contacts 11b and 11c enhances soft error tolerance, such that effects, e.g., suppression of memory data corruption, are expected.

The gate electrode 2c and the contacts 14a to 14c have the same structures as the gate electrode 2a and the contacts 11a to 11c, and the description thereof will be thus omitted herein.

As described above, according to the first embodiment, while the parasitic capacitances of the contacts connected with the bit lines are reduced, soft error tolerance is increased. It is therefore possible to enhance read speed and increase data stability. Furthermore, the reduced parasitic capacitances of the contacts connected with the bit lines result in a decrease in charge and discharge current during a data write operation, and hence in a decrease in power consumption.

It should be noted that the contact 11a may be moved to the right-hand side of FIG. 1 so as to be located further away from the contact 11b. It also should be noted that the contact 11a, 11b, or 11c may have a smaller diameter, so that the distance between contacts 11a and 11b or the distance between contacts 11a and 11c is increased. Then, the parasitic capacitance of the contact 11a is reduced further.

Moreover, the contact 11c may be moved to the left-hand side of FIG. 1 so as to be located closer to the contact 11b. Then, the parasitic capacitance of the contact 11c is increased further.

### Second embodiment

FIG. 2 illustrates the layout of an SRAM memory cell according to a second embodiment. A memory cell 1A includes nMOS transistors 11, 12, 13, and 14 and pMOS transistors 15 and 16. The gate electrodes 2a′ and 2c′ of the nMOS transistors 11 and 14 have a liner shape and are connected with a word line WL via conductive projections 3a′ and 3b′. The projections 3a′ and 3b′ are formed in the direction away from contacts 11a and 14a, respectively. Specifically, the projection 3a′ is formed in the downward direction and the projection 3b′ is formed in the upward direction in FIG. 2. The other members in the memory cell 1A are the same as those in the memory cell 1 illustrated in FIG. 1 and are thus identified by the same reference numerals, and the description thereof will be omitted herein.

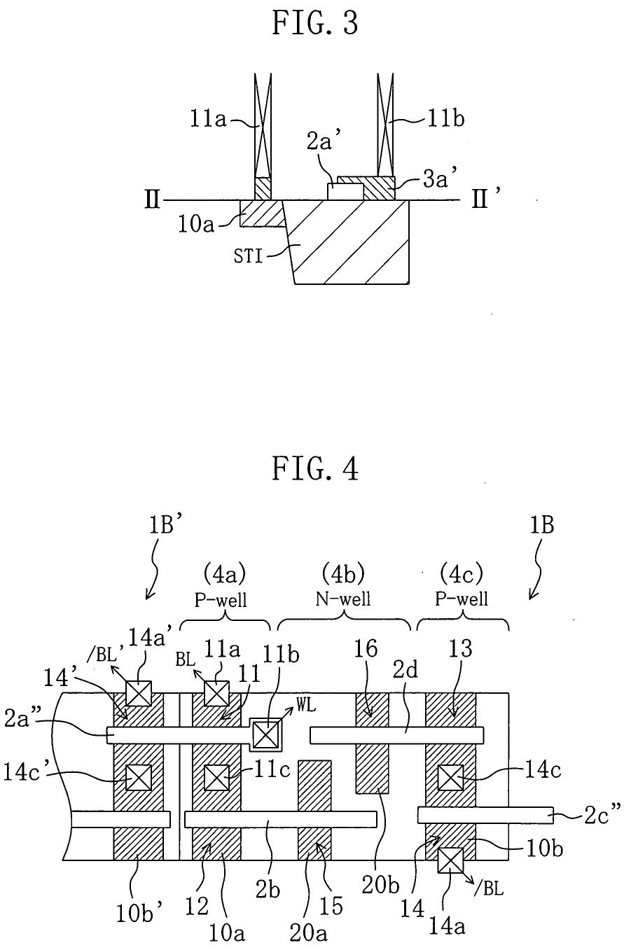

FIG. 3 is a cross-sectional view taken along the line II-II′ of FIG. 2. As shown in FIG. 3, the projection 3a′ is preferably in contact with the upper and side faces of the gate electrode 2a′. Then, the contact area, in which the projection 3a′ and the gate electrode 2a′ are in contact with each other, is increased, thereby reducing the contact resistance between the projection 3a′ and the gate electrode 2a′. The region at the right of the gate 2a′ as viewed in FIG. 3, on which the projection 3a′ is formed, is a device isolation region STI where electrical problems, such as electrical leakage, do not occur. The projection 3b′ has the same structure as the projection 3a′.

As described above, according to the second embodiment, the shapes of the gate electrodes 2a′ and 2c′ are linear, as has been conventional. Thus, it is possible to reduce the parasitic capacitances of the contacts connected with the bit lines without any particular mask pattern changes. Furthermore, variation in gate shape caused during fabrication is also suppressed.

### Third embodiment

FIG. 4 illustrates the layout of an SRAM memory cell according to a third embodiment. A memory cell 1B includes nMOS transistors 11, 12, 13, and 14 and pMOS transistors 15 and 16. A memory cell 1B′, whose structure is the same as that of the memory cell 1B but is upside down, is adjacent to the left of the memory cell 1B, as viewed in FIG. 4. Although not shown, a memory cell similar to the memory cell 1B′ is also adjacent to the right of the memory cell 1B, as viewed in FIG. 4.

A gate electrode 2a″ of the nMOS transistor 11 is shared by an nMOS transistor 14′ included in the memory cell 1B′. The gate electrode 2a″ is connected with a word line WL by a contact 11b. The contact 11b is formed outside a region surrounded by contacts 11a, 11c, 14a′, and 14c′ connected with the source and drain regions of the two nMOS transistors 11 and 14′ that share the gate electrode 2a″. Specifically, the contact 11b is provided to the right of an n-type doped region 10a as viewed in FIG. 4. The other members are the same as those in the memory cell 1 illustrated in FIG. 1 and are thus identified by the same reference numerals, and the description thereof will be omitted herein.

By this structure, the distance between the contact 14a′ and the contact 11b is increased, which enables the parasitic capacitance of the contact 14a′ to be reduced significantly. In cases in which the space where the contact 11b is provided cannot be secured, the n-type doped region 10a may be moved to the left-hand side.

Due to the symmetry of the circuit having the mirror inversion structure, the parasitic capacitance of the contact 14a, like the parasitic capacitance of the above-described contact 14a′, is reduced greatly, resulting in the creation of an imbalance between the parasitic capacitance of the contact 11a and the parasitic capacitance of the contact 14a. In that case, the speed at which data is read from the memory cell 1B is limited by the data read speed of the bit line BL connected with the contact 11a having the larger parasitic capacitance. It is therefore preferable that the bit lines BL and /BL be twisted together to have a twisted structure. The twisted structure enables the capacitances of the bit lines BL and /BL to be equal.

As described above, according to the third embodiment, the parasitic capacitance of the contact connected with the bit line /BL is reduced significantly, whereby the data read speed of the entire memory cell is enhanced.

The structures of the SRAM memory cells described in the first to third embodiments are effective in a semiconductor memory device that includes a DRAM having stacked capacitors, in which the parasitic capacitances of contacts are particularly likely to be large.

What is claimed is:

1. A semiconductor memory device including an SRAM, wherein a gate electrode of a MOS transistor connected with a word line and a bit line in the SRAM has a projection extending in a direction away from a contact electrically connecting a drain region of the MOS transistor and the bit line, and
a contact electrically connecting the gate electrode and the word line is provided in the projection.

2. The semiconductor memory device of claim 1, comprising a DRAM,
wherein the bit line in the SRAM and a bit line in the DRAM are formed in a common interconnect layer.

3. The semiconductor memory device of claim 2, wherein the DRAM has a stacked capacitor, and
the layer where the bit lines are formed is above the capacitor.

4. A semiconductor memory device including an SRAM, the device comprising:
a conductive projection, which is in contact with a gate electrode of a MOS transistor connected with a word line and a bit line in the SRAM and extends in a direction away from a contact electrically connecting a drain region of the MOS transistor and the bit line, and
a contact electrically connecting the projection and the word line.

5. The semiconductor memory device of claim 4, comprising a DRAM,
wherein the bit line in the SRAM and a bit line in the DRAM are formed in a common interconnect layer.

6. The semiconductor memory device of claim 5, wherein the DRAM has a stacked capacitor, and
the layer where the bit lines are formed is above the capacitor.

7. A semiconductor memory device including an SRAM, wherein a first MOS transistor and a second MOS transistor are connected to a common word line in the SRAM and have a common gate electrode, and a contact that electrically connects the gate electrode and the word line is provided outside a region surrounded by contacts that are connected with a drain region and a source region respectively of the first MOS transistor and by contacts that are connected with a drain region and a source region respectively of the second MOS transistor.

8. The semiconductor memory device of claim 7, comprising a DRAM,
wherein a bit line in the SRAM and a bit line in the DRAM are formed in a common interconnect layer.

9. The semiconductor memory device of claim 8, wherein the DRAM has a stacked capacitor, and
the layer where the bit lines are formed is above the capacitor.

10. The semiconductor memory device of claim 7, wherein a bit line and an inverted bit line in the SRAM are twisted together, the inverted bit line being obtained by inverting logic of the bit line.
